(19) United States
(12) Patent Application Publication
(10) Pub. No.: US 2026/0287678 A1
(43) Pub. Date: Sep. 24, 2026

(54) SYSTEM AND METHOD FOR MANAGING ELECTRIC GRID

(71) Applicant: Safegrid Oy, Espoo (FI)

(72) Inventors: Tapio Mäntysalo, Hevonpää (FI); Amir Farughian, Turku (FI)

(73) Assignee: Safegrid Oy, Espoo (FI)

(21) Appl. No.: 19/476,251

(22) PCT Filed: Apr. 29, 2024
(86) PCT No.: PCT/FI2024/050201

§ 371 Date: Oct. 17, 2025

(30) Foreign Application Priority Data
May 4, 2023 (FI) 20235495

(51) Int. Cl. G01R 31/52; G01R 19/00; G01R 31/08

(52) U.S. Cl. CPC G01R 31/52; G01R 19/0053; G01R 19/0092; G01R 31/08

(57) ABSTRACT

A system and a method for managing an electric grid with a substation having a transformer with a transformer neutral thereof grounded via a grounding impedance. The system includes a current sensing unit that measures ground or neutral current at the transformer neutral and traveling wave fault recording units installed on feeder lines to detect and record arrival times of traveling waves generated by a fault event. A processing arrangement communicates with the current sensing unit and the traveling wave fault recording units, receiving information about ground or neutral current and traveling wave arrival times. The processing arrangement detects earth faults in feeder lines, or the substation based on the received information and computes the fault location in response to detecting an earth fault, using the information about the arrival time of traveling waves.

### TECHNICAL FIELD

The present disclosure relates to a system for managing an electric grid with a substation having a transformer with a transformer neutral thereof grounded via a grounding impedance. Moreover, the present disclosure relates to a method for managing an electric grid with a substation having a transformer with a transformer neutral thereof grounded via a grounding impedance.

### BACKGROUND

An electric grid is a critical infrastructure that requires continuous monitoring and maintenance to ensure the reliable delivery of power. Generally, an electric grid comprises power lines, power poles, transformers, switching circuits, protection circuits, and so forth. Such electric grid may be prone to faults occurring due to lighting, wind, trees falling on lines, apparatus failure, and the like. As an example, the fault may cause over current, under voltage, unbalancing of three phases, high voltage surges, and the like. These faults may cause deviations in voltage values and current values from their nominal ranges in the electric grids. Examples of the faults include but are not limited to, transient faults, ground faults, ground faults, arcing faults, short circuit faults, open circuit faults, overload faults, broken conductors, lost phases, and partial discharges. Most of the faults in the electric grid are transient in nature. For example, a transient fault may occur due to a tree contact, for example, trees falling onto overhead lines, incautious excavation performed nearby underground cables, a bird or an animal contact, a lightning strike, a clash of conductors due to an external force (such as high wind speed), cracks or impurities in insulation material, and the like. The management of the electric grid includes accurately detecting faults and errors in the electric grid and/or the electrical components operating therein. Specifically, one of the main challenges in managing the electric grid is the accurate detection and location of faults, which can lead to power outages and damage to equipment. To address this issue, various fault detection and location methods have been developed over the years; however known techniques have certain limitations. For instance, transformers in the electric grid are equipped with a compensation coil to mitigate the effects of ground faults in the electric grid, but that can make ground fault detection using conventional fault indicators more challenging. This is because the compensation coil is tuned to introduce an inductive current that opposes and cancels out the capacitive current generated by the fault. This compensation minimizes the fault current to a very low level, close to zero. Since conventional fault indicators rely on detecting increased current levels associated with faults, the reduced fault current can make it difficult for these indicators to detect the ground fault.

Therefore, in light of the foregoing discussion, there exists a need to overcome the aforementioned limitations/drawbacks.

### SUMMARY

The aim of the present disclosure is to provide a system and a method having an additional earth current sensing current sensor to the transformer neutral or the sum currents of a grounded neutral transformer, which is capable of measuring earth currents very accurately, as all earth current will flow through it, making the classification of earth faults much simpler. The aim of the present disclosure is achieved by a system and a method for managing an electric grid with a substation having a transformer with a transformer neutral thereof grounded via a grounding impedance as defined in the appended independent claims to which reference is made to. Advantageous features are set out in the appended dependent claims.

Throughout the description and claims of this specification, the words “comprise”, “include”, “have”, and “contain” and variations of these words, for example “comprising” and “comprises”, mean “including but not limited to”, and do not exclude other components, items, integers or steps not explicitly disclosed also to be present. Moreover, the singular encompasses the plural unless the context otherwise requires. In particular, where the indefinite article is used, the specification is to be understood as contemplating plurality as well as singularity, unless the context requires otherwise.

### BRIEF DESCRIPTION OF THE DRAWINGS

FIGS. 1A-1C are illustrations of schematics of a conventional setup for an electric grid;

FIGS. 2A-2D are illustrations of different configurations of a system for managing an electric grid with a substation having a transformer with a transformer neutral thereof grounded via a grounding impedance, in accordance with one or more embodiments of the present disclosure; and

FIG. 3 is an illustration of a flowchart listing steps involved in a method for managing an electric grid with a substation having a transformer with a transformer neutral thereof grounded via a grounding impedance, in accordance with one or more embodiments of the present disclosure.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practising the present disclosure are also possible.

In a first aspect, the present disclosure provides a system for managing an electric grid with a substation having a transformer with a transformer neutral thereof grounded via a grounding impedance, the system comprising:
a current sensing unit associated with the transformer neutral, wherein the current sensing unit is configured to measure a ground current or a neutral current at the transformer neutral;
one or more traveling wave fault recording units installed on one or more feeder lines connected to the transformer, with each of the one or more feeder lines having one of the one or more traveling wave fault recording units installed therein, wherein each of the one or more traveling wave fault recording units are configured to detect and record arrival times of traveling wave signals generated by a fault event in the corresponding feeder line; and
a processing arrangement in communication with the current sensing unit and the one or more traveling wave fault recording units, the processing arrangement configured to:
   receive information about the ground current or the neutral current from the current sensing unit, and the arrival times of traveling wave signals from the one or more traveling wave fault recording units;
   detect an earth fault in any of the one or more feeder lines or at the substation based on the received information about the ground current or the neutral current; and
   compute, in response to detection of the earth fault in any of the one or more feeder lines or at the substation, a fault location of the fault event in the one or more feeder lines based on the received information about the arrival times of traveling wave signals.

In the present system, the current sensing unit accurately measures the ground or neutral current at the transformer neutral, enabling the detection of ground or earth faults in the electric grid. Meanwhile, the traveling wave fault recording units installed on the one or more feeder lines detect and record the arrival times of travelling wave signals generated by the fault event, providing valuable data for identifying fault locations. The processing arrangement receives this information and combines it to detect earth faults in any of the feeder lines or at the substation. Furthermore, the processing arrangement computes the fault location based on the received information about the arrival times of traveling wave signals. This synergistic combination of components ensures precise detection of earth faults and accurate identification of fault locations, contributing to a more reliable and efficient electric grid management.

In a second aspect, the present disclosure provides method for managing an electric grid with a substation having a transformer with a transformer neutral thereof grounded via a grounding impedance, the method comprising:
measuring a ground current or a neutral current at the transformer neutral using a current sensing unit associated therewith;
detecting and recording arrival times of traveling wave signals generated by a fault event in a corresponding one of one or more feeder lines, using one or more traveling wave fault recording units installed on the one or more feeder lines connected to the transformer, with each of the one or more feeder lines having one of the one or more traveling wave fault recording units installed therein;
detecting an earth fault in any of the one or more feeder lines or at the substation based on information about the ground current or the neutral current; and
computing, in response to detection of the earth fault in any of the one or more feeder lines or at the substation, a fault location of the fault event in the one or more feeder lines based on information about the arrival times of traveling wave signals.

In the present method, measuring the ground or neutral current at the transformer neutral using the current sensing unit allows for the detection of ground or earth faults in the electric grid. Recording the arrival times of traveling wave signals generated by the fault event in the corresponding feeder lines, using traveling wave fault recording units, provides essential data for identifying fault locations. Detecting earth faults in any of the feeder lines or at the substation is achieved based on the information about the ground or neutral current, while computing the fault location in response to the detection of earth faults is done based on the information about the arrival times of traveling wave signals. This synergistic combination of steps ensures precise detection of earth faults and accurate identification of fault locations, leading to more reliable and efficient electric grid management.

Herein, the transformer is a main transformer (with two terms being interchangeably used hereinafter) which is an electrical device installed at the substation, responsible for stepping up or stepping down the voltage levels in the electric grid. This main transformer helps in the effective transmission and distribution of electrical energy from the power generation sources to the consumers. The main transformer has a primary winding connected to the high-voltage side, typically the transmission lines, and a secondary winding connected to the medium-voltage side, which supplies power to the feeder lines that distribute electricity to various consumers, or alternatively, when used in generation side such as windmill parks, the feeder lines feed generated electricity from the generators to the transformer.

As used herein, the term “transformer neutral” refers to the neutral point of a main transformer, such as a three-phase transformer, which is the common connection point of the three windings in a wye (star) configuration. The neutral point is often grounded to provide a reference point for the system voltage and to facilitate the flow of fault currents during earth faults. In some cases, the transformer neutral may be directly connected to the ground or connected via the grounding impedance. Alternatively, the transformer neutral may be implemented as a separate “neutral transformer”, which is a distinct transformer that is specifically designed to manage the neutral point of a main transformer associated therewith. The neutral transformer is connected to the neutral point of the main transformer and is grounded via the ground impedance.

This separate neutral transformer allows for more precise control of the neutral current and facilitates fault detection and locating in the electrical grid. For instance, the neutral transformer provides improved accuracy in measuring the earth current, as all earth current flows through it and the associated current sensing unit. This arrangement enables easier classification of earth faults and enhances the effectiveness of fault locating techniques. Additionally, the separate neutral transformer allows for better management and control of the grounding system, which can lead to improved safety and reliability of the electrical grid. Therefore, the transformer neutral may either be an integral part of the main transformer or a separate neutral transformer. Both configurations aim to provide an effective grounding point for the system and facilitate fault detection and locating in the electrical grid. However, the separate neutral transformer offers greater flexibility and control, potentially leading to improved performance and safety.

Further, as used herein, the grounding impedance helps in managing the transformer neutral and the flow of fault currents during earth faults in the electrical grid. In present examples, the grounding impedance may be in the form of a resistor, compensation coil, or arc suppression coil, and it is typically connected between the transformer neutral (or the neutral point of a separate neutral transformer) and the ground. For example, the resistor, as the grounding impedance, limits the fault current during an earth fault, which helps protect the electrical equipment from damage due to high fault currents. By controlling the magnitude of fault current, such a resistor may also minimize the risk of arc flash incidents and reduce the mechanical and thermal stresses on the electrical system components. Alternatively, the compensation coil, also known as a Petersen coil, is an inductive grounding impedance that is used to balance the capacitive earth fault current in the electrical grid. When an earth fault occurs, the capacitive current flowing to the ground generates a reactive power, and the compensation coil is designed to produce an equal and opposite reactive power, effectively compensating for the capacitive fault current. This approach helps reduce the fault current to a minimum, which can mitigate the impact of the fault on the electrical grid and improve system stability. The arc suppression coil is a type of grounding impedance that is specifically designed to eliminate or reduce the arcing in switchgear during earth faults. The arc suppression coil is an adjustable inductive coil that may be tuned to match the capacitive earth fault current, effectively neutralizing the fault current and extinguishing the arc, which may reduce the risk of equipment damage and improve the safety of the electrical grid. The choice of grounding impedance depends on various factors, such as the type of electrical grid, the desired fault current level, and the specific requirements of the electrical grid. Regardless of the type of grounding impedance used, the goal is to manage the flow of fault currents during earth faults, protect the electrical equipment, and facilitate fault detection and locating in the electrical grid.

Further, the one or more traveling wave fault recording units are installed on the one or more feeder lines that are connected to the main transformer. These feeder lines are responsible for distributing electricity from the substation to various consumers in the electrical grid. Each feeder line is equipped with one of the traveling wave fault recording units, which helps in the fault detection and location process. The traveling wave fault recording units are specifically designed and configured to detect and record the arrival times of traveling wave signals generated by a fault event within their corresponding feeder lines. It may be understood that traveling waves are rapid voltage and current changes that propagate along power lines when a fault occurs, such as a short circuit or a ground fault. These waves travel at a speed close to the speed of light and can provide valuable information for identifying the location and nature of the fault. The traveling wave fault recording units continuously monitor the feeder lines and, upon detection of traveling wave signals, record the arrival times of these wave signals at their respective locations. This information is then transmitted to the processing arrangement, which analyses the arrival times from different units and computes the fault location within the feeder lines.

It may be appreciated by a person skilled in the art that in a conventional double-ended traveling wave fault locating system, at least one transient signal sensor is required at the substation end for each feedline line in addition to transient signal sensor further down the feeder line at other end for each of the traveling wave fault recording unit. That is, for instance, in a substation with 20 outgoing feeder lines, this would necessitate installing sensors at 20 outgoing terminations, which is a significant number and can be a costly endeavour. One alternative solution involves installing a single sensor at the transformer medium voltage bushings. However, this approach presents some drawbacks. Firstly, earth current cannot be measured at isolated transformers because there is no earth connection, so the system may only detect earth faults if the sensors out on the feeder line detect them. Secondly, traveling wave fault location is not possible using current sensors at the transformer windings, as the transformer behaves as a very high-frequency load at high-frequencies. Consequently, only very small transient currents can be measured by the sensors.

The present system addresses these issues by using the current sensing unit associated with the transformer neutral, which is the point at which the transformer's windings are connected to the grounding system via the grounding impedance. The current sensing unit plays a crucial role in detecting and identifying earth faults within the electric grid. The current sensing unit is specifically designed and configured to measure either the ground current or the neutral current at the transformer neutral. Herein, the “ground current” refers to the current that flows through the grounding system, while neutral current is the sum of currents flowing through each of the three-phase conductors in a balanced system. Measuring the neutral current may be particularly useful for detecting earth faults, as any imbalance between the three-phase currents indicates a possible fault. The current sensing unit accurately measures any earth current since all earth current flows through it, and thereby classifies earth faults. When an earth fault occurs, the ground current or neutral current measured by the current sensing unit will change, indicating a possible fault in the electric grid.

In present examples, the current sensing unit may be implemented using various types of sensors, such as Rogowski coils, current transformers, or Hall effect sensors, each with its own characteristics and advantages. For example, Rogowski coils are non-contacting current sensors that consist of a helical coil of wire wound around a non-magnetic core. These sensors measure the rate of change of current (di/dt) passing through a conductor by generating a voltage proportional to this rate. Since they do not saturate or suffer from hysteresis, Rogowski coils are suitable for measuring a wide range of currents, including high-frequency and high-amplitude transients. Current transformers (CTs) are magnetic devices that transform the primary current (input) into a proportional secondary current (output). They have a high degree of accuracy, excellent linearity, and the ability to measure a wide range of currents. Hall effect sensors are based on the Hall effect principle, in which a voltage is generated across a conductor when it is placed in a magnetic field perpendicular to the direction of current flow. These sensors can measure both DC and AC currents and have a wide frequency response, making them suitable for various applications, including fault detection. Each of these sensor types is capable of accurately measuring the currents at the transformer neutral, providing valuable information for fault detection and analysis.

The processing arrangement serves as the central component in the system, facilitating communication between the current sensing unit and the one or more traveling wave fault positioning units. Herein, in a non-limiting example, the processing arrangement may be remote to, and be wirelessly connected to the current sensing unit and the one or more traveling wave fault positioning units. The processing arrangement is responsible for receiving, processing, and analysing the data collected by the sensors to detect earth faults and compute fault locations within the electrical grid. Herein, first, the processing arrangement gathers data on the ground current or neutral current from the current sensing unit. Additionally, it collects the arrival times of traveling wave signals generated by fault events from the one or more traveling wave fault positioning units installed on the feeder lines. Using the received information about the ground current or neutral current, the processing arrangement analyses the data to detect any earth faults occurring in the feeder lines or at the substation. This detection process helps identify faults in the system that may cause instability, power outages, or damage to equipment. Once an earth fault is detected in the transformer or the feeder lines, the processing arrangement calculates the fault location within the one or more feeder lines. This calculation is based on the received information about the arrival times of traveling wave signals. Accurate fault location enables the grid operators to pinpoint the exact position of the issue, allowing for faster and more efficient repairs or maintenance.

Therefore, by measuring the ground current or neutral current at the transformer neutral, the current sensing unit enables accurate and reliable detection of earth faults within the electrical grid. This information is then transmitted to the processing arrangement, which analyses the data to detect and identify the presence of an earth fault in any of the feeder lines or at the substation. Such information, in conjunction with the arrival times of traveling wave signals recorded by the traveling wave fault recording units, allows the processing arrangement to compute the fault location and initiate appropriate corrective actions to maintain the stability and reliability of the electric grid.

In an embodiment, the current sensing unit is installed at an input of the grounding impedance, or at input(s) of the transformer neutral. Herein, the current sensing unit is strategically installed at specific locations to effectively measure ground current or neutral current for fault detection and analysis. By installing the current sensing unit at the input of the grounding impedance, it is possible to accurately measure the ground current or neutral current that flows through this component during an earth fault. In this configuration, the current sensing unit is connected directly to the input of the grounding impedance, which is the point where the transformer neutral connects to the grounding impedance. Alternatively, by installing the current sensing unit at the input(s) of the transformer neutral, it is possible to measure the neutral current directly from the transformer windings, providing an accurate representation of the sum of currents flowing through each of the three-phase conductors. In this configuration, the current sensing unit is connected to the input(s) of the transformer neutral, which are the points where the three-phase conductors from the transformer windings connect to the neutral point. The current sensing unit in this setup can either have individual sensors for each of the three-phase conductors or have a single sensor that covers all three conductors.

In an embodiment, the current sensing unit is configured to measure the ground current in case of the transformer being a grounded transformer or a low-impedance grounded transformer. That is, in the case of the main transformer being the grounded transformer or the low-impedance grounded transformer, the transformer neutral is directly connected to the ground or connected through a low-impedance path. In these scenarios, the current sensing unit is configured to measure the ground current. Since the ground current flows through the neutral point, it accurately represents the fault current associated with earth faults. Herein, the current sensing unit, equipped with suitable sensors, may measure the ground current and provide accurate fault detection and location information for the electric grid.

In an embodiment, the current sensing unit is configured to measure the neutral current in case of the transformer being an ungrounded transformer or a high-impedance grounded transformer. That is, in the case of the main transformer being the ungrounded transformer or the high-impedance grounded transformer, the transformer neutral is not directly connected to the ground or is connected through a high-impedance path. The ground fault current in such cases may be significantly lower than in grounded systems, making it difficult to detect earth faults. In these scenarios, the current sensing unit is configured to measure the neutral current. The neutral current is the sum of the three-phase currents and is indicative of an earth fault in the system. Measuring the neutral current helps detect earth faults even when the ground fault current is low. By using appropriate sensors and configurations, the current sensing unit may accurately measure the neutral current and provide reliable fault detection and location information for the electric grid.

In an embodiment, the current sensing unit comprises three current measurement coils, with each of the three current measurement coils coupled to one of three phase conductors of the transformer neutral or the grounding impedance, and wherein the current sensing unit is configured to measure a sum of currents of the three phase conductors, to measure the neutral current. That is, to achieve neutral current measurement, the current sensing unit may include three current measurement coils, each specifically designed to be coupled to one of the three-phase conductors of the transformer neutral or the grounding impedance. This configuration allows the current sensing unit to effectively measure the currents flowing in each phase conductor of the system. By coupling each current measurement coil to its respective phase conductor, the current sensing unit may detect and measure the individual currents in each of the three-phase conductors. Once the currents have been measured, the current sensing unit is configured to calculate the sum of these currents, representing the neutral current in the system. The use of three current measurement coils ensures that the current sensing unit may capture the current information from each phase conductor accurately and reliably. Furthermore, this configuration enables the current sensing unit to account for any phase imbalances or other issues that may arise within the system, ensuring a comprehensive and accurate neutral current measurement.

In an embodiment, the current sensing unit comprises:
a single current measurement coil coupled to each of three phase conductors of the transformer, and wherein the current sensing unit is configured to measure a sum of currents of the three phase conductors via the single current measurement coil, to measure the neutral current; or
two or more current measurement coils, with each of the two or more current measurement coils coupled to one or two phase conductors so as to cover each of three phase conductors of the transformer, and wherein the current sensing unit is configured to measure a sum of currents of the three phase conductors via the two or more current measurement coils, to measure the neutral current.

As discussed, the current sensing unit is designed to accurately measure the neutral current by capturing the sum of currents in the three-phase conductors. There are two possible configurations for the current sensing unit, each with its unique setup and functionality. In the single current measurement coil configuration, the current sensing unit may include a single current measurement coil that is coupled to each of the three-phase conductors of the transformer. The single current measurement coil is designed to capture the sum of the currents flowing through the three-phase conductors, providing the neutral current measurement. This setup simplifies the measurement process, requiring only one coil to obtain the required information. However, the single current measurement coil configuration may be less accurate in situations where there are significant phase imbalances or other issues within the system. In the alternative two or more current measurement coils configuration, the current sensing unit may include two or more current measurement coils, each coupled to one or two of the three-phase conductors, ensuring that each phase conductor is covered. In this second configuration, the current sensing unit is designed to measure the sum of currents flowing through the three-phase conductors by collecting and processing the data from the multiple current measurement coils, resulting in the neutral current measurement. Herein, in general, the choice between the single current measurement coil configuration and the multiple current measurement coils configuration may depend on factors such as measurement accuracy requirements, complexity, and flexibility needed for a specific application.

In an embodiment, in case of the substation with two transformers adapted to be used alternatively to feed the one or more feeder lines, the system comprises separate current sensing units associated with each of the said two transformers, and wherein each of the said separate current sensing units is configured to measure the neutral current through the grounding impedance associated with respective one of the said two transformers. That is, in cases where the substation utilizes two transformers that are adapted to be used alternatively to feed the one or more feeder lines, the system incorporates separate current sensing units associated with each of the two transformers. The purpose of these separate current sensing units is to measure the neutral current flowing through the grounding impedance connected to each respective transformer. It is important to mention that when the feeding transformer is changed, the grounding impedance, such as the compensation coil, typically remains the same for the same feeders. By employing separate current sensing units, the system ensures accurate measurements and fault detection for each transformer, independent of the other. Furthermore, the use of separate current sensing units allows for greater flexibility and adaptability in the substation design, as this makes it possible to switch between transformers without any disruption to the fault detection and location process.

In an embodiment, the system comprises at least one traveling wave fault recording unit installed on each one of the one or more feeder lines associated with the transformer in the substation. In this configuration, each feeder line connected to the transformer in the substation has at least one traveling wave fault recording unit installed. This allows for the detection and recording of traveling wave signals on each individual feeder line, which enhances the system's ability to identify fault events and their locations accurately. By monitoring each feeder line separately, the present system may pinpoint faults quickly and effectively, enabling grid operators to address issues promptly and reduce the impact on the overall grid performance.

Alternatively, or additionally, the system may include at least one traveling wave fault recording unit installed on the cables interconnecting the current busbars, which, in turn, are connected to the feeder lines. This configuration focuses on monitoring the interconnections between busbars, which are primary distribution lines within the electrical grid. By installing traveling wave fault recording units on these cables, the present system may detect, and record traveling waves associated with fault events occurring within any of the feeder lines associated with the corresponding interconnected busbars.

Optionally, the traveling wave fault recording units are positioned in close proximity to the busbars of the substation. This strategic placement enables the system to accurately monitor the critical points within the electrical grid, ensuring timely detection of faults and minimizing potential impacts on grid performance. In particular, as the traveling wave fault recording unit is located close to the busbars, the distance that traveling wave signals need to travel to reach the unit is minimized; this reduces the chances of signal attenuation, ensuring that the recorded signals are of high quality and may be accurately analysed by the processing arrangement.

According to an embodiment, the present system, in addition to detecting earth faults, may also be implemented for detecting short circuits faults in the electrical grid. In the system, the short circuits may be detected by installing current coils on all three phases of the main transformer. The sum current of the three-phase conductors may, thus, be easily obtained by connecting three current measurement coils on the phase conductors in series or, preferably, for improved accuracy, with a larger current sensing coil covering all three-phase conductors. As a result, a minimal setup requires only one current sensing unit with four current sensing coils/elements per substation. This current sensing unit has inputs for all three-phase currents of the transformer to measure the ground/neutral current as well as detect any short-circuit in the transformer at the substation in the electric grid.

Further, according to an embodiment, the system may further include additional high-frequency sensors in close proximity to the substation busbars that interconnect the outgoing feeders. These sensors are designed to measure high-frequency transient signals with a high signal-to-noise ratio, contributing to the traveling wave fault positioning process. By increasing the sensitivity of traveling wave location detection, these high-frequency sensors effectively enhance the system's ability to pinpoint fault locations. This is because the high-frequency fault signals used for traveling wave fault locating exhibit high current levels within the station busbars, flowing from one feeder to another. Thereby, large substations with multiple busbars that are physically distant from one another may benefit from the use of multiple high-frequency sensors.

Specifically, when high-frequency transient signals, generated by faults on feeder lines, reach the substation, they continue along the paths with the smallest impedances. The lowest impedances are typically found in other feeders, as feeder lines are transmission lines with relatively low impedance. The main transformer and the neutral transformer, on the other hand, are high-impedance inductive devices at high frequencies, which means that high-frequency transient currents will enter these devices with significant attenuation. As a result, the high-frequency transient current signals may simply be measured at one feeder output or the busbar interconnect. It may be appreciated that since transient signals may be either common mode (phase-to-earth fault) or differential mode (phase-to-phase fault), it may be required to use two high-frequency sensors to accommodate both scenarios. If the high-frequency sensors are not installed at busbar interconnects, such sensors may be positioned at the feeder line exit points. However, it is preferable to have at least two such sensors in place to account for situations where one feeder connection may be open, such as during maintenance or line cuts.

According to an embodiment, the present system is further configured to locate precursor partial discharge events using the traveling wave signals without yet any measurable fault current; and further to combine the location information of said precursors events with a possibly later occuring small, but measurable increase in neutral or ground current to detect and locate very high-impedance earth faults before a catastrophic fault occurs. As an example, there could be a tree branch which is leaning on overhead line wires, and first causes small but locatable sparks which sometime later will increase the neutral or ground current, which may soon escalate as a catastrophic fault causing service interruption.

The present system, as described in the preceding paragraphs, offers an innovative approach for monitoring the electrical grid by utilizing traveling wave sensors on feeder lines. This enables the detection of precursor partial discharge events through the analysis of traveling waves even before a measurable fault current occurs. By combining the location information of these precursor events with potential small increases in neutral or ground current, the present system may detect and locate very high-impedance earth faults before they result in catastrophic damage. This early warning system enables operators to address faults before they escalate and cause significant damage. Combining the location information of precursor events with subsequent changes in neutral or ground current allows the system to pinpoint the location of high-impedance earth faults with greater precision. This helps streamline maintenance and repair efforts, ultimately reducing downtime and costs associated with grid management.

The present disclosure also relates to the method as described above. Various embodiments and variants disclosed above, with respect to the aforementioned system, apply mutatis mutandis to the method.

In an embodiment, the method further comprises measuring the ground current or the neutral current at an input of the grounding impedance, or at input(s) of the transformer neutral, by installing the current sensing unit thereat.

In an embodiment, the method further comprises measuring the ground current in case of the transformer being a grounded transformer or a low-impedance grounded transformer.

In an embodiment, the method further comprises measuring the neutral current in case of the transformer being an ungrounded transformer or a high-impedance grounded transformer.

In an embodiment, the method further comprises measuring a sum of currents of three phase conductors to measure the neutral current, by providing three current measurement coils in the current sensing unit, with each of the three current measurement coils coupled to one of the three phase conductors of the transformer neutral or the grounding impedance.

In an embodiment, the method further comprises measuring a sum of currents of three phase conductors to measure the neutral current, by:
providing a single current measurement coil in the current sensing unit, with the single current measurement coil coupled to each of the three phase conductors of the transformer; or
providing two or more current measurement coils in the current sensing unit, with each of the two or more current measurement coils coupled to one or two phase conductors so as to cover each of three phase conductors of the transformer.

In an embodiment, in case of the substation with two transformers adapted to be used alternatively to feed the one or more feeder lines, the method further comprises measuring the neutral current through the grounding impedance associated with the respective one of said two transformers by using separate current sensing units associated with each of the said two transformers.

Conventional systems for managing ground faults often face limitations in terms of accuracy and efficiency. Ground faults are typically addressed by dividing feeders into sections, de-energizing the faulty feeder section when a fault is detected and located. However, ground fault detection is challenging in compensated networks due to the potentially small ground current. Large substations with numerous outgoing feeder lines, sometimes as many as 40, rely on separate protection relays and circuit breakers for each line. Additionally, feeders may be long and have multiple branches. While incorporating fault-passage indicators or extra protection relays and circuit breakers on lengthy feeder lines can help limit the area to be searched for a fault and reduce the time to isolate it, this approach is still not ideal. Traveling-wave fault location indicators can locate faults more accurately between two sensors, which can be situated anywhere from 1 km apart in dense city networks to 50 km apart on extensive transmission lines. However, in a substation that serves as a junction point for the grid, each outgoing feeder should ideally have its own traveling-wave fault indicators installed to detect ground faults on those feeders. Installing a fault indicator only at the output of a transformer in a compensated network equipped with an arc suppression, compensation, or Petersen coil cannot detect a ground fault since the transformer is fully isolated from the ground. This limitation in conventional systems hinders effective fault detection and management, potentially leading to increased downtime and costs associated with grid maintenance.

The system and the method of the present disclosure are capable of accurately detecting faults and their locations in the electric grid, even in cases where the fault current is compensated by an arc suppression coil or other grounding impedance. The present disclosure by incorporating the current sensing unit enhances fault detection accuracy for both short circuits and earth/ground faults by working in conjunction with the traveling wave fault recording units. The present disclosure leverages the traveling wave fault recording units, which incorporates fault indicators (sensors) on at least one, and possibly all, outgoing feeders. When a fault occurs, it is detected between at least two sensors placed along the feeder line. Multiple sensors may be necessary for each feeder to ensure comprehensive coverage, and these sensors are typically situated several kilometers away from the substation. Such inclusion of additional high-frequency sensors at strategic locations within the substation improves the performance and reliability of the traveling wave fault positioning system by increasing its sensitivity to fault-induced transient signals, which ultimately leads to more accurate detection and localization of faults within the electrical grid.

The present disclosure significantly simplifies the monitoring process by using a single current sensing unit installed in the substation, rather than requiring numerous sensors at the substation. The current sensing unit measures the transformer's current in the substation to detect earth faults, short circuits, wire snaps, partial discharge events, and more. This approach ensures highly accurate earth current measurement for ground/earth fault detection while requiring only one sensor per main transformer, as opposed to multiple sensors for every outgoing feeder of the substation. In the present disclosure, the use of reduced number of sensors, and even in some cases, a single current sensing unit at the substation, in combination with traveling wave sensors on feeder lines, allows for efficient and cost-effective monitoring of the electrical grid. By utilizing this innovative approach, the present disclosure addresses the limitations of conventional systems, leading to improved fault detection and management for the electrical grid.

### DETAILED DESCRIPTION OF THE DRAWINGS

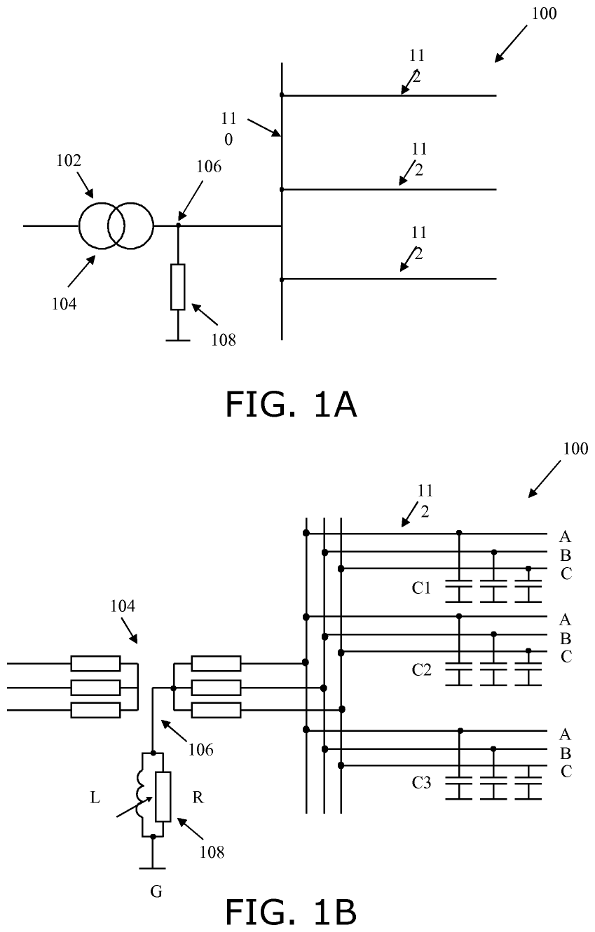

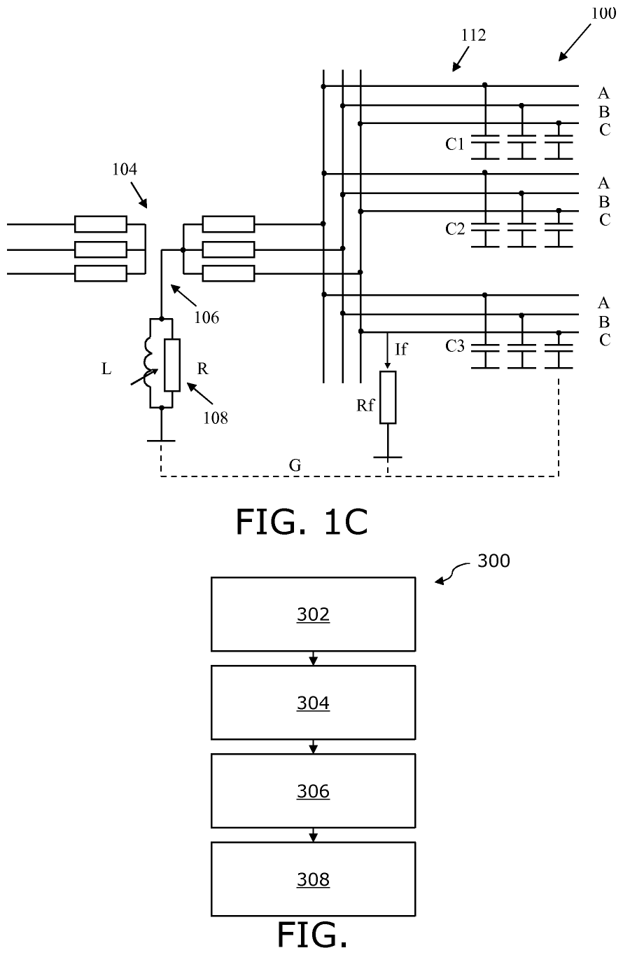

Referring to FIGS. 1A-1C, in combination, illustrated are various schematics of a conventional setup for an electric grid (as represented by reference numeral 100) with a substation 102 having a transformer 104 with a transformer neutral 106 thereof grounded via a grounding impedance 108. In FIG. 1A, the transformer 104 is depicted along with the grounding impedance 108, a busbar 110, and multiple feeder lines 112 connected to the busbar 110. FIG. 1B illustrates a high-voltage network that supplies the primary side of the transformer 104 with a voltage of, for example, 110 kV, which is then converted to a medium voltage of 20 kV. A coil ‘L’ and a resistor ‘R’ are arranged in parallel and connected between a star point of the transformer 104 and earth/ground ‘G’, as the grounding impedance 108. The secondary side of the transformer 104 is connected to the busbar 110 with the feeder lines 112, each including phase conductors ‘A-C’, with each of the phase conductors ‘A-C’ including an earth capacitance ‘C1-C3’. FIG. 1C depicts flow of current in case of a fault. As shown, in the event of a fault occurring in any of the phase conductors ‘A-C’, the capacitive fault current (denoted as ‘If’ in FIG. 1C) flows into the ground ‘G’. During an earth fault, the capacitive current passing through the fault initially forms an arc on the ionized path of the fault. As the arc forms, its voltage across it drops to zero, causing the arc to extinguish later. The overvoltage resulting from the arc may be mitigated by the grounding impedance 108 connected to the transformer 104. In the case of the grounding impedance 108, it is connected to the transformer neutral 106 and extinguishes the arc by neutralizing the capacitive current passing through it.

When an earth or ground fault takes place, a fault resistance ‘Rf’ exists from the fault point to the ground. The capacitive fault current ‘If’ returns to the network via ground and shunt capacitances (3×C3 in parallel). The current flows from the healthy feeders to the transformer neutral 106 and then back to the fault point, as demonstrated in FIG. 1C. Further, in the absence of a fault, the charging currents generated by the shunt capacitances of the phase conductors ‘A-C’ in the electrical grid 100 cancel each other out. When a fault occurs, the voltage of the faulted phase is determined by the product of the fault current ‘If’ and the fault resistance ‘Rf’. Consequently, the voltage of the faulted phase decreases, while the voltages of the healthy phases increase.

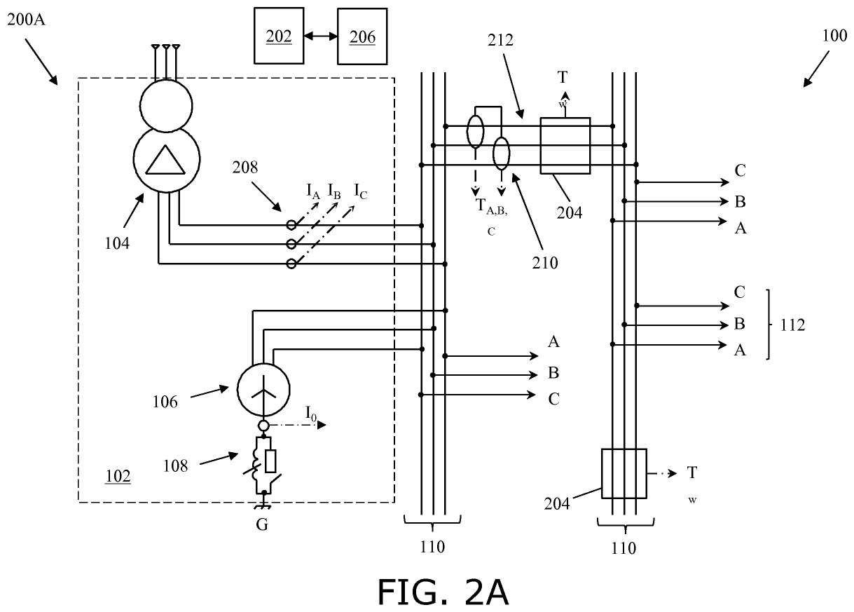

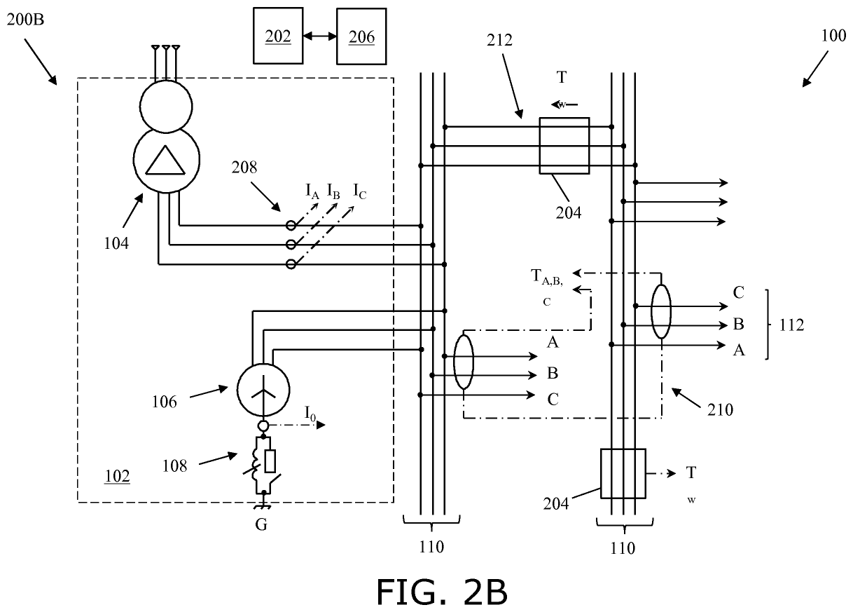

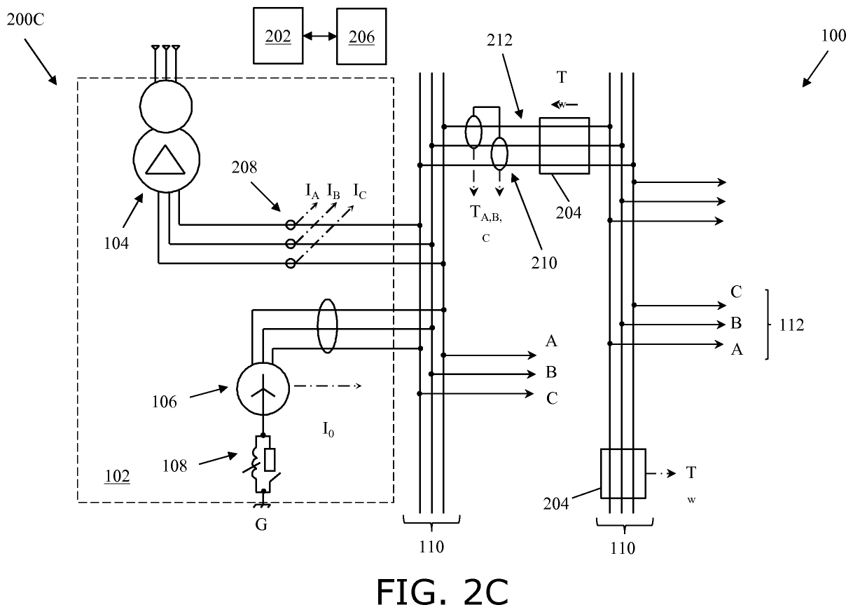

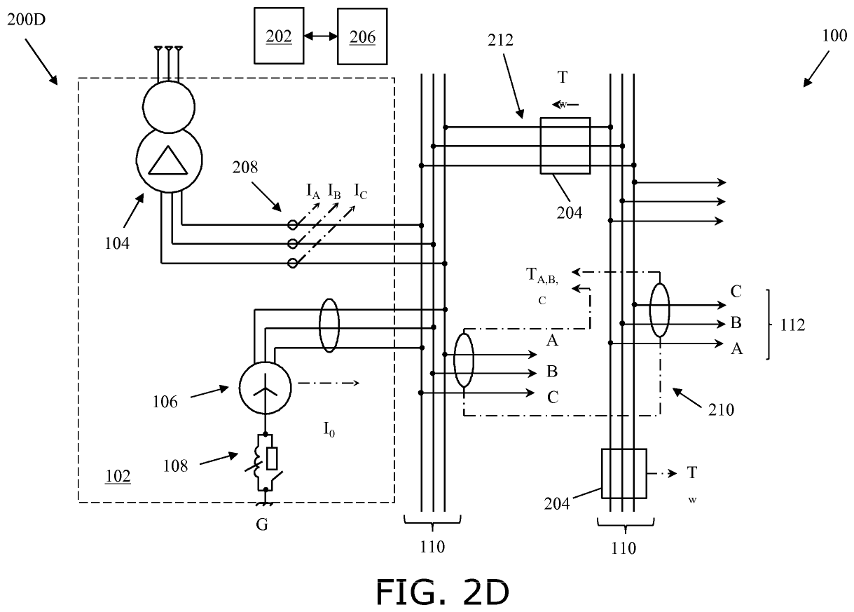

Referring to FIGS. 2A-2D, illustrated are exemplary depictions of different configurations of a system (represented by reference numerals 200A-200D) for managing the electric grid 100 with the substation 102 having the transformer 104 with the transformer neutral 106 thereof grounded via the grounding impedance 108, in accordance with one or more embodiments of the present disclosure. As illustrated, the system 200A-200D includes a current sensing unit 202, one or more traveling wave fault recording units 204, and a processing arrangement 206. The current sensing unit 202 is associated with the transformer neutral 106. The current sensing unit 202 is configured to measure a ground current Io. Specifically, the current sensing unit 202 receives the ground current Io from corresponding current elements/coils, for example wirelessly. The one or more traveling wave fault recording units 204 are installed on the one or more feeder lines 112 connected to the transformer 104, with each of the one or more feeder lines 112 having one of the one or more traveling wave fault recording units 204 installed therein. The one or more traveling wave fault recording units 204 are configured to detect and record arrival times of traveling wave signals T_{w} generated by a fault event in the corresponding feeder line 112. The processing arrangement 206 is in communication with the current sensing unit 202 and the one or more traveling wave fault recording units 204. The system 200A-200D may further include current measurement coils 208 on all three phases of the transformer 104 to measure sum current of the three-phase conductors I_{A}, I_{B}, I_{C}. The system 200A-200D may further include high-frequency sensors 210 in close proximity to the busbars 110 to measure high-frequency transient signals T_{A, B, C}. The readings for the sum current I_{A}, I_{B}, I_{C} and the high-frequency transient signals T_{A,B,C} are provided to the processing arrangement 206 for processing, for detecting short circuits and for effectively pinpoint fault locations, respectively. In the system 200A-200D, the various measurements I₀; T_{w}; I_{A}, I_{B}, I_{C}; and T_{A,B,C} may be received wirelessly by the processing unit 204, as depicted by dashed-dotted lines.

In the system 200A of FIG. 2A, the current sensing unit 202 is installed at an input of the grounding impedance 108 to measure the ground current I₀. Also, the high-frequency sensors 210 are coupled to an interconnect (as represented by reference numeral 212) connecting two busbars 110 in the electric grid 100. In the system 200B of FIG. 2B, the high-frequency sensors 210 are, alternatively, coupled to the feeder lines 112 in the electric grid 100 in contrast to the system 200A of FIG. 2A. Further, in the system 200C of FIG. 2C, the current sensing unit 202 is installed at input(s) of the transformer neutral 106 to measure the ground current I₀. Also, the high-frequency sensors 210 are coupled to the interconnect 212 connecting two busbars 110 in the electric grid 100. In the system 200D of FIG. 2D, the high-frequency sensors 210 are, alternatively, coupled to the feeder lines 112 in the electric grid 100 in contrast to the system 200C of FIG. 2C. It may be appreciated that the system 200A-200D may have further variations (combinations) possible without departing from the scope and the spirit of the present disclosure.

Referring to FIG. 3, illustrated is a flowchart listing steps involved in a method 300 for managing an electric grid with a substation having a transformer with a transformer neutral thereof grounded via a grounding impedance, in accordance with an embodiment of the present disclosure. At step 302, the method 300 includes measuring a ground current or a neutral current at the transformer neutral using a current sensing unit associated therewith. At step 304, the method 300 includes recording arrival times of traveling wave signals generated by a fault event in a corresponding one of one or more feeder lines, using one or more traveling wave fault recording units installed on the one or more feeder lines connected to the transformer, with each of the one or more feeder lines having one of the one or more traveling wave fault recording units installed therein. At step 306, the method 300 includes detecting an earth fault in any of the one or more feeder lines or at the substation based on information about the ground current or the neutral current. At step 308, the method 300 includes computing, in response to detection of the earth fault in any of the one or more feeder lines or at the substation, a fault location of the fault event in the one or more feeder lines based on information about the arrival times of traveling wave signals. It may be appreciated that the above steps are only illustrative and other alternatives can also be provided where one or more steps are added, one or more steps are removed, or one or more steps are provided in a different sequence without departing from the spirit and the scope of the present disclosure.

1.-16. (canceled)

17. A system for managing an electric grid with a substation having a transformer with a transformer neutral grounded via a grounding impedance, the system comprising:
a current sensing unit associated with the transformer neutral, wherein the current sensing unit is configured to measure a ground current or a neutral current at the transformer neutral;
one or more traveling wave fault recording units installed on one or more feeder lines connected to the transformer, each of the one or more traveling wave fault recording units configured to detect and record arrival times of traveling wave signals generated by a fault event in the corresponding feeder line;
one or more high-frequency sensors positioned at the feeder line exit points or at the interconnections of busbars within the substation;
a processing arrangement in communication with the current sensing unit, the one or more traveling wave fault recording units, and the one or more high-frequency sensors, the processing arrangement configured to:
receive information about the ground current or the neutral current from the current sensing unit, and the arrival times of traveling wave signals from the one or more traveling wave fault recording units;
detect an earth fault or a differential mode fault in any of the one or more feeder lines or at the substation based on the received information about the ground current or neutral current; and
compute, in response to detection of an earth fault or a differential mode fault, a fault location of the fault event in the one or more feeder lines based on the received information about the arrival times of traveling wave signals and the detected transient signals.

18. The system according to claim 17, wherein the high-frequency sensors are configured to detect both common mode and differential mode transient signals, thereby enhancing fault location accuracy by reducing signal attenuation.

19. The system according to claim 17, wherein the current sensing unit is installed at an input of the grounding impedance, or at input(s) of the transformer neutral.

20. The system according to claim 17, wherein the current sensing unit is configured to measure the ground current in case of the transformer being a grounded transformer or a low-impedance grounded transformer.

21. The system according to claim 17, wherein the current sensing unit is configured to measure the neutral current in case of the transformer being an ungrounded transformer or a high-impedance grounded transformer.

22. The system according to claim 21, wherein the current sensing unit comprises three current measurement coils, with each of the three current measurement coils coupled to one of three phase conductors of the transformer neutral or the grounding impedance, and wherein the current sensing unit is configured to measure a sum of currents of the three phase conductors, to measure the neutral current.

23. The system according to claim 21, wherein the current sensing unit comprises:
a single current measurement coil coupled to each of three phase conductors of the transformer, and wherein the current sensing unit is configured to measure a sum of currents of the three phase conductors via the single current measurement coil, to measure the neutral current; or
two or more current measurement coils, with each of the two or more current measurement coils coupled to one or two phase conductors so as to cover each of three phase conductors of the transformer, and wherein the current sensing unit is configured to measure a sum of currents of the three phase conductors via the two or more current measurement coils, to measure the neutral current.

24. The system according to claim 21, wherein, in case of the substation with two transformers adapted to be used alternatively to feed the one or more feeder lines, the system comprises separate current sensing units associated with each of the said two transformers, and wherein each of the said separate current sensing units is configured to measure the neutral current through the grounding impedance associated with respective one of the said two transformers.

25. The system according to claim 17 further comprising at least one traveling wave fault recording unit installed on each one of the one or more feeder lines associated with the transformer in the substation.

26. The system according to claim 17, wherein the system is configured to locate precursor partial discharge events using the traveling wave signals without yet any measurable fault current; and to combine the location information of said precursors events with a possibly later occuring small, but measurable increase in neutral or ground current to detect and locate very high-impedance earth faults before a catastrophic fault occurs.

27. The system according to claim 17, wherein the high-frequency sensors are configured to measure high-frequency transient signals with a high signal-to-noise ratio, enhancing the detection of fault-induced transient signals for precise fault location in large substations with multiple busbars that are physically distant from one another.

28. The system according to claim 17, wherein the one or more high-frequency sensors are positioned in proximity to busbars of the substation, wherein the high-frequency sensors are configured to detect transient signals caused by faults in both common mode (phase-to-earth) and differential mode (phase-to-phase) faults.

29. A method for managing an electric grid with a substation having a transformer with a transformer neutral thereof grounded via a grounding impedance, the method comprising:
measuring a ground current or a neutral current at the transformer neutral using a current sensing unit associated therewith;
detecting and recording arrival times of traveling wave signals generated by a fault event in a corresponding one of one or more feeder lines, using one or more traveling wave fault recording units installed on the one or more feeder lines connected to the transformer;
sensing, by one or more high-frequency sensors positioned at the feeder line exit points or at the interconnections of busbars within the substation, high-frequency signals associated with the fault event;
receiving, by a processing arrangement in communication with the current sensing unit, the one or more traveling wave fault recording units, and the one or more high-frequency sensors information about the ground current or the neutral current from the current sensing unit; and arrival times of traveling wave signals from the one or more traveling wave fault recording units;
detecting an earth fault or a differential mode fault in any of the one or more feeder lines or at the substation based on information about the ground current or neutral current; and
computing, in response to detection of an earth fault or a differential mode fault, a fault location of the fault event in the one or more feeder lines based on information about the arrival times of traveling wave signals and the detected transient signals.

30. The method according to claim 29, wherein the method comprises detecting both common mode and differential mode transient signals, thereby enhancing fault location accuracy by reducing signal attenuation.

31. The method according to claim 29 further comprising measuring the ground current or the neutral current at an input of the grounding impedance, or at input(s) of the transformer neutral, by installing the current sensing unit thereat.

32. The method according to claim 29 further comprising measuring the ground current in case of the transformer being a grounded transformer or a low-impedance grounded transformer.

33. The method according to claim 29 further comprising measuring the neutral current in case of the transformer being an ungrounded transformer or a high-impedance grounded transformer.

34. The method according to claim 33 further comprising measuring a sum of currents of three phase conductors to measure the neutral current, by providing three current measurement coils in the current sensing unit, with each of the three current measurement coils coupled to one of the three phase conductors of the transformer neutral or the grounding impedance.

35. The method according to claim 33 further comprising measuring a sum of currents of three phase conductors to measure the neutral current, by:
providing a single current measurement coil in the current sensing unit, with the single current measurement coil coupled to each of the three phase conductors of the transformer; or
providing two or more current measurement coils in the current sensing unit, with each of the two or more current measurement coils coupled to one or two phase conductors so as to cover each of three phase conductors of the transformer.

36. The method according to claim 33, wherein, in case of the substation with two transformers adapted to be used alternatively to feed the one or more feeder lines, the method further comprises measuring the neutral current through the grounding impedance associated with the respective one of said two transformers by using separate current sensing units associated with each of the said two transformers.

37. The method according to claim 29, wherein the high-frequency sensors are configured to measure high-frequency transient signals with a high signal-to-noise ratio, enhancing the detection of fault-induced transient signals for precise fault location in large substations with multiple busbars that are physically distant from one another.

38. The method according to claim 29, wherein the method comprises detecting transient signals caused by events in both common mode (phase-to-earth) and differential mode (phase-to-phase) faults, using one or more high-frequency sensors positioned in proximity to busbars of the substation.
